(19) United States
(12) Patent Application Publication
(10) Pub. No.: US 2007/0030660 A1
(43) Pub. Date: Feb. 8, 2007

(54) Retention device for mounting expansion cards

(75) Inventors: Wen-Tang Peng, Tu-Cheng (TW); Guang-Yi Zhang, Shenzhen (CN); De-Yi Shi, Shenzhen (CN)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: HON HAI Precision Industry CO., LTD, Tu-Cheng City (TW)

(21) Appl. No.: 11/344,350

(22) Filed: Jan. 30, 2006

(30) Foreign Application Priority Data
Aug. 2, 2005 (CN) 200520062527.3

(51) Int. Cl. H05K 7/14

(52) U.S. Cl. 361/801

(57) ABSTRACT

A retaining device for retaining expansion cards (60) with cover plates (62) includes a rear panel (20), a retaining bar (40), and a clip (50). The rear panel includes a pair of hooks (24), and a card rack (30). The card rack includes a supporting plate (32) for supporting the bent portions (624) of the expansion cards, and a pair of mounting plates (36) extending upwardly at two ends of the supporting flange. A pivot hole (362) is defined in each of the mounting plates and includes a round portion (366), and an entry (364) communicating with the round portion and an edge of a corresponding mounting plate. The retaining bar includes a pair of neck portions (48) rotatably engaging in the pivot holes. The clip is attached to the retaining bar and includes a pair of catching parts (54) engaging with the hooks.

### BACKGROUND OF THE INVENTION

1. Field of the Invention

The present invention relates to a retention device for retaining expansion cards in a computer enclosure, and particularly to a retention device which readily secures a plurality of expansion cards in a computer enclosure and allows convenient removal of the expansion cards therefrom.

2. Background of the Invention

In order to upgrade the operating capabilities of a personal computer, a plurality of expansion cards is operatively installed in the computer enclosure. Typical types of expansion cards include network cards, sound cards, graphics accelerator cards and multi-media cards, etc. These expansion cards may be installed in the computer enclosure during its original manufacture or by the computer purchaser.

U.S. Pat. No. 4,745,524 discloses a plurality of mounting systems for mounting a plurality of expansion cards inside a computer chassis. Each mounting system includes a pressing element and a screw to secure a separate cover plate of a corresponding expansion card. However, installing screws one by one is time-consuming and cumbersome. Moreover, during installation/removal of the expansion cards, one or more of the screws can easily fall into the crowded interior of the computer, thereby creating a difficult retrieval problem.

Another conventional retention device is disclosed in U.S. Pat. No. 5,317,483. The retention device includes an elongated fixing bar with one end rotatably connected to a rear panel of the computer enclosure, and the other end movably secured to the rear panel, therefore a plurality of cover plates is pressed by the fixing bar. However, said other end of the fixing bar is secured to the rear panel by a fixing screw which increases inconvenience in installation/removal process. Additionally, because the fixing bar is flat and slim, and the series of cover plates might be on different heights, the fixing bar will fail to press on the cover plates which are on a lower position. Therefore, the untouched, lower positioned cover plates might not be securely attached to the rear panel. When suffered from shock or vibration, the cover plates will easily break away from the rear panel.

What is needed is to provide a retention device which readily retains expansion cards in a computer enclosure and allows convenient removal of the expansion cards therefrom.

### SUMMARY

An exemplary retaining device for retaining expansion cards with cover plates to a computer enclosure includes a rear panel, a retaining bar, and a clip. The rear panel includes a pair of hooks, and a card rack. The card rack includes a supporting plate for supporting the bent portions of the expansion cards, and a pair of mounting plates extending upwardly at two ends of the supporting flange. A pivot hole is defined in each of the mounting plates and includes a round portion, and an entry communicating with the round portion and an edge of a corresponding mounting plate. The retaining bar includes a pair of neck portions rotatably engaging in the pivot holes. The clip is attached to the retaining bar and includes a pair of catching parts engaging with hooks.

Other advantages and novel features of the invention will become more apparent from the following detailed description when taken in conjunction with the accompanying drawings, in which:

### BRIEF DESCRIPTION OF THE DRAWINGS

FIG. 1 is an exploded, isometric view of a retention device in accordance with a preferred embodiment of the present invention, the retention device includes a retaining bar, and a clip;

FIG. 2 is an enlarged view of the retaining bar of FIG. 1, but viewed from another aspect;

FIG. 3 is an assembled view of the retaining bar and the clip of FIG. 1;

FIGS. 4 and 5 are assembled views of FIG. 1, showing the retention device in a locked state and an unlocked state; and

FIG. 6 is an enlarged view of a circled portion VI of FIG. 5.

### DETAILED DESCRIPTION OF THE EMBODIMENT

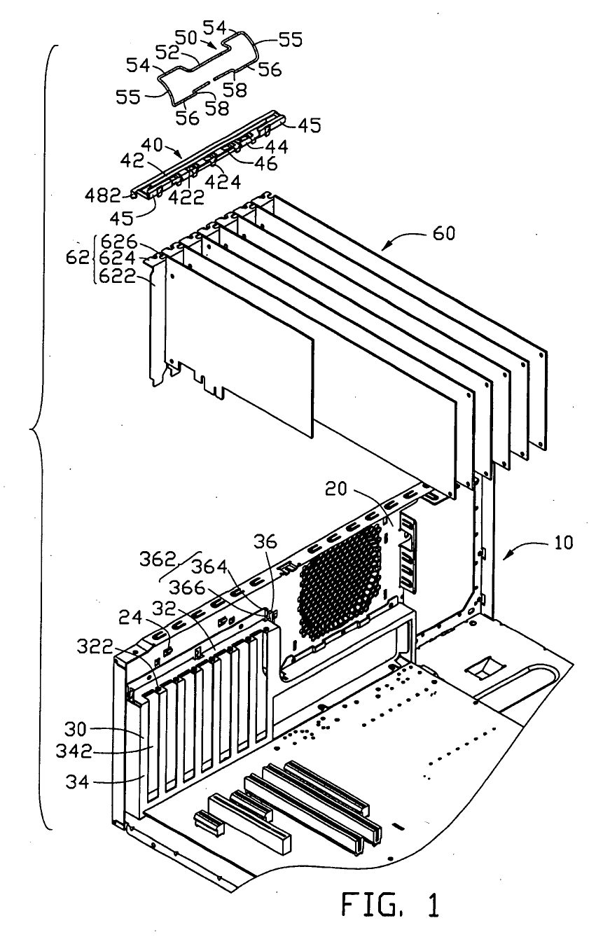

Referring to FIG. 1, a retention device of an electronic device like a computer in accordance with the preferred embodiment of the present invention is used to fix a plurality of functional parts like expansion cards 60 with cover plates 62 to a computer enclosure 10. The retention device includes a rear panel 20, a retaining bar 40, and a resilient member like a clip 50 attached to the retaining bar 40. The retaining bar 40 and the clip 50 form a retaining assembly to retain expansion cards 60 to the rear panel 20.

Each cover plate 62 includes a rectangular elongated portion 622 connected to the expansion card 60, and a bent portion 624 extending perpendicularly from one end of the elongated portion 622. A cutout 626 is defined in the bent portion 624.

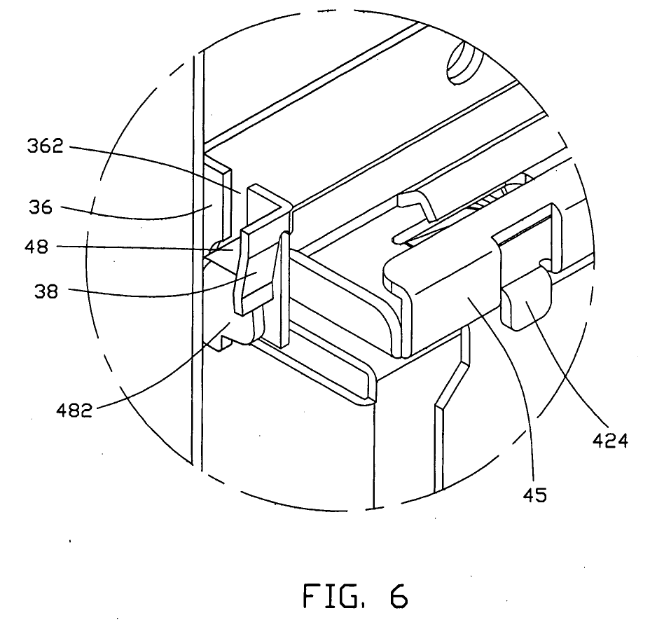

The rear panel 20 includes a card rack 30 formed from an inner side thereof, and a pair of hooks 24 extending therefrom above the card rack 30. The card rack 30 includes a base plate 34, and a supporting plate 32 extending perpendicularly from the base plate 34. A plurality of expansion card slots 342 is defined in the base plate 32 parallel to each other, and further extends to the supporting plate 32, having a similar profile with the cover plates 62. A pair of mounting plates 36 extends perpendicularly from two opposite ends of the supporting plate 34. A pivot hole 362 is defined in each of the mounting plates 36. Each of the pivot holes 362 includes a round portion 366, and an entry 364 communicating with the round portion 366 and an edge of a corresponding mounting plate 34. Referring also to FIG. 6, a first locating tab 38 extends perpendicularly from an edge of each of the mounting plates 36. A plurality of positioning posts 322 is formed on the supporting plate 32.

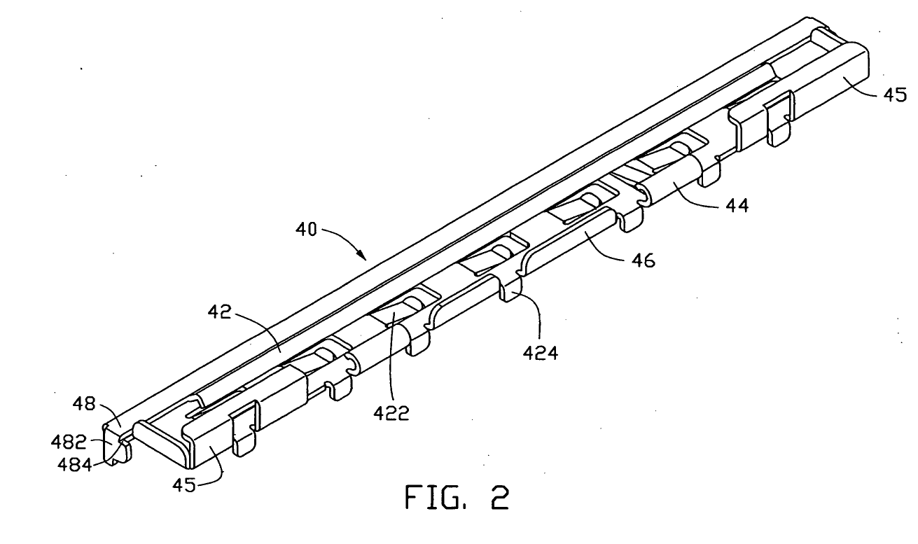

Referring to FIG. 2, the retaining bar 40 includes an elongated main body 42, a pair of neck portion 48 extending from two ends of the main body 42, and a pair of second locating tabs 482 depending from the corresponding neck portion 48. A shoulder 484 is defined in an upper portion of each of the second locating tabs 482. A plurality of evenly spaced resilient fingers 422 are stamped from main body 42. A plurality of pressing tabs 424 extends downwardly from a lateral side of the main body 42, for pressing or abutting against the elongated portions 622 of the cover plates 62. A plurality of evenly spaced positioning tabs 46 and sleeves 44 extends upwardly from the lateral side of the main body 42. A pair of flanges 45 extends upwardly from end portions of the lateral side of the main body 42.

The clip 50 is made of a winding wire and includes a handle part 52, a pair of catching parts 54 formed at two end of the handle 52, a pair of fixing parts 56, a pair of free parts 58 formed from distal ends of the fixing parts 56, and a pair of connecting parts generally disposed between the engaging parts and fixing parts 56. The free parts 58 are parallel to the handle 52. The engaging parts 54 are parallel to the fixing parts 56.

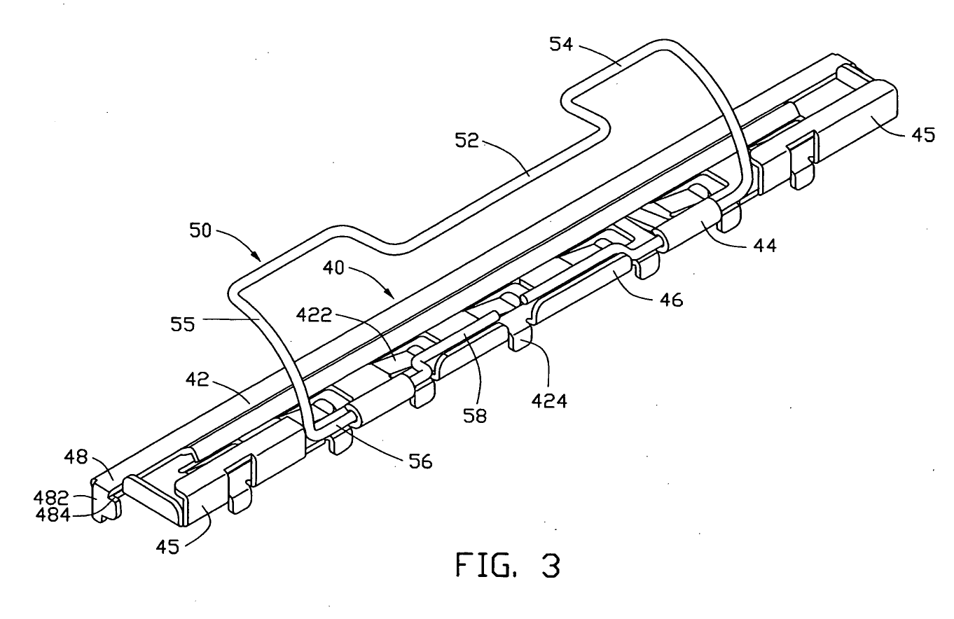

Referring to FIG. 3, in assembly, the clip 50 is assembled to the retaining bar 40. The fixing parts 56 are extended through the sleeves 44, and the free parts 58 abut against the positioning tabs 46. The connecting parts 55 abut against inner ends of the flanges 45.

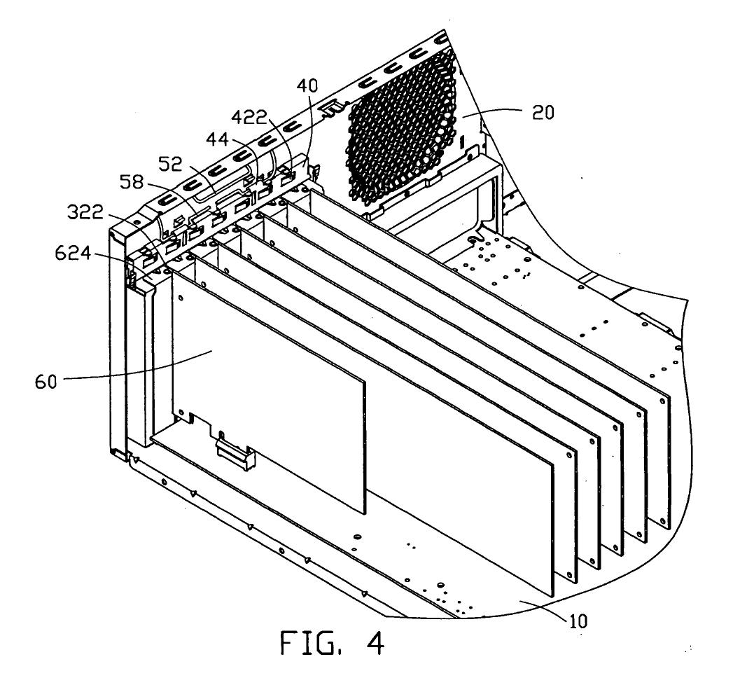

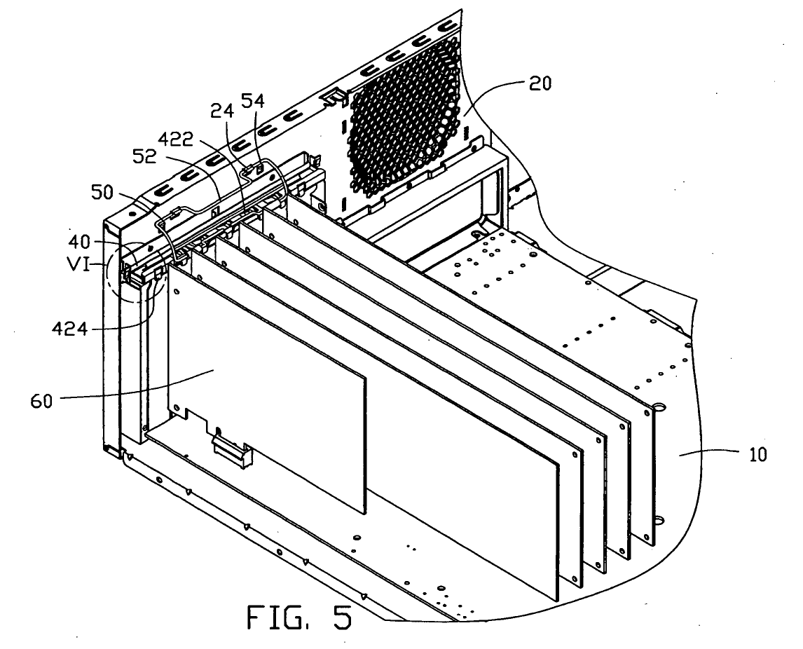

Referring to FIGS. 4 and 5, the assembled retaining bar 40 is attached to the card rack 30. Rotating the retaining bar 40, the neck portions 48 are vertically displaced into the entry 364 and horizontally received in the round portions 366 of the pivot holes 362. Bottom ends of the first locating tabs 38 engagingly abut against the shoulders 484 of the second locating tabs 482 of the retaining bar 40. Then the cover plates 30 with expansion cards 20 are attached to the slots 622 of the card rack 60. The cutouts 626 of the expansion cards 60 receive the positioning posts 322 of the card rack 30. Draw the handle part 52 of the clip 50 to rotate the retaining bar 40 to become a bend assembled relationship, the resilient fingers 422 of the retaining bar 40 are pressing the bent portions 624 of the cover plates 60; the pressing tabs 424 of the retaining bar 40 are abutting against the elongated portions 6222 of the cover plates 60. Thus, all the cover plates 30 are securely attached to the slots 342 of the card rack 30. The catching parts 54 of the clip 50 are locked to the hooks 24 of the rear panel 20.

In disassembly, simply draw the handle part 52 of the clip 50 to disengage the catching parts 54 from the hooks 24 of the rear panel 20, and rotate the retaining bar 40 away the card rack 30 to become a stretch assembled relationship, then the cover plates 62 together with the expansion cards 60 can be easily taken away from the card rack 30. During the disassembly process, the retaining bar 40 is connected in the mounting pivot holes 362, therefore, when the cover plates 62 are attached to the slots 342 again, simply rotate the retaining bar 40 towards the card rack 30 to complete assembly. The whole process is convenient, simple, and can decrease cost and save manpower.

It is believed that the present embodiment and its advantages will be understood from the foregoing description, and it will be apparent that various changes may be made thereto without departing from the spirit and scope of the invention or sacrificing all of its material advantages, the example hereinbefore described merely being preferred or exemplary embodiment of the invention.

We claim:

1. A retention device for retaining a plurality of expansion cards with cover plates to a computer enclosure, each of the cover plates having an elongated portion and a bent portion, the mounting assembly comprising:
a rear panel comprising a pair of hooks, and a supporting plate extending therefrom to support the cover plates, a pair of mounting plates extending from end portions of the supporting plate, a pivot hole defined in each of the mounting plates;
a retaining bar comprising an elongated main body, the main body comprising a pair of neck portions pivotally engaging in the pivot holes of the mounting plate, and a plurality of resilient pressing tabs to press the bent portions of the cover plates; and
a clip attached to the retaining bar and comprising a pair of catching parts engaging with the hooks of the rear panel.

2. The retention device as claimed in claim 1, wherein each of the pivot holes further comprises a round portion, and an entry communicating with the round portion and an edge of a corresponding mounting plate.

3. The retention device as claimed in claim 1, wherein a first locating tab extends from each of the mounting plates, a second locating tab depends from each of the neck portions of the retaining bar to engage with the first locating tab.

4. The retention device as claimed in claim 3, wherein each of the second tabs further comprises a shoulder to engage with an end of the first locating tab.

5. The retention device as claimed in claim 1, wherein the retaining bar comprises a pair of sleeves, and a pair of flanges extending from the main body thereof, the clip comprises a pair of fixing parts extending through the sleeves, and a pair of connecting parts formed at one of ends of the fixing parts to abut against ends portion of the flanges.

6. The retention device as claimed in claim 5, wherein the retaining bar further comprises a pair of positioning parts formed at the other ends of the fixing parts, the clip further comprises a pair of free ends to abut against the positioning parts.

7. The retention device as claimed in claim 1, wherein the clip further comprises a handle part disposed between the catching parts.

8. The retention device as claimed in claim 1, wherein retaining bar further comprises a plurality of resilient fingers pressing the bent portions of the cover plates on the supporting plate.

9. A retention device for mounting a plurality of expansion cards with cover plates to a computer enclosure, each of the cover plates having an elongated portion and a bent portion, the mounting assembly comprising:
a rear panel comprising at least one hook, and a rack arranged at an inner side of the rear panel; and
a retaining assembly movably attached to the rack and comprising a retaining bar, and a winding wire fixed to the retaining bar and engaging with said hook, the retaining bar rotated to press the bent portions of the cover plates on the rack.

10. The retention device as claimed in claim 9, wherein the rack comprises a supporting plate to support the cover plates, and a pair of mounting plates extending from end portions of the supporting plate.

11. The retention device as claimed in claim 10, wherein retaining bar further comprises a plurality of resilient fingers pressing the bent portions of the cover plates on the supporting plate.

12. The retention device as claimed in claim 10, wherein each of the mounting plates defines a pivot hole therein, the retaining bar comprises an elongated main body, the main body comprising a pair of neck portions pivotally engaging in the pivot holes.

13. The retention device as claimed in claim 12, wherein each of the pivot holes further comprises a round portion, and an entry communicating with the round portion and an edge of a corresponding mounting plate.

14. The retention device as claimed in claim 12, wherein a first locating tab extends from each of the mounting plates, a second locating tab depends from each of the neck portions of the retaining bar to engage with the first locating tab.

15. The retention device as claimed in claim 9, wherein the winding wire is a clip fixed to the retaining bar.

16. The retention device as claimed in claim 15, wherein the retaining bar comprises a pair of sleeves, and a pair of flanges extending from the main body thereof, the clip comprises a pair of fixing parts extending through the sleeves, and a pair of connecting parts formed at one of ends of the fixing parts to abut against ends portion of the flanges.

17. The retention device as claimed in claim 16, wherein the retaining bar further comprises a pair of positioning parts formed at the other ends of the fixing parts, the clip further comprises a pair of free ends to abut against the positioning parts.

18. An electronic device comprising:
a functional part installable in said electronic device for functional extension of said electronic device;
a side panel of said electronic device partially enclosing said electronic device and defining at least one slot so as to expose a portion of said functional part therefrom; and
a retaining assembly movably attachable to said side panel and capable of performing a stretch status thereof occupying a first space along said side panel and a bend status thereof occupying a second space along said side panel smaller than said first space, said retaining assembly capable of retaining said portion of said functional part to said side panel when said retaining assembly is in said bend status thereof, and capable of releasing said portion of said functional part to be removable away from said side panel when said retaining assembly is in said stretch status thereof.

19. The electronic device as claimed in claim 16, wherein said retaining assembly comprises a resilient member and a retaining bar attachable to said resilient member for retaining said portion of said functional part, said retaining assembly is in said stretch status when said resilient member moves farther away from said retaining bar and is in a relaxing condition, and is in said bend status when said resilient member moves closer to said retaining bar and is in a compressed condition for applying an urging force onto said retaining bar.
